(19) United States
(12) Patent Application Publication
(10) Pub. No.: US 2007/0125491 A1
(43) Pub. Date: Jun. 7, 2007

(54) METHOD OF REMOVING PARTICLE ON SUBSTRATE, APPARATUS THEREFOR, AND COATING AND DEVELOPMENT APPARATUS

(75) Inventors: Akira Yonemizu, Koshi-shi (JP); Akihiro Fujimoto, Koshi-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTON LIMITED, Minato-ku (JP)

(21) Appl. No.: 11/559,675

(22) Filed: Nov. 14, 2006

(30) Foreign Application Priority Data
Dec. 2, 2005 (JP) 2005-349189

(51) Int. Cl. B32B 37/12; B08B 7/00; H01L 21/00

(52) U.S. Cl. 156/285; 134/6; 15/3; 15/102; 156/247; 156/281

(57) ABSTRACT

Particles attached to the back surface of a substrate are removed easily, reliably and quickly. An adhesive sheet is placed with an adhesive portion thereof up on a support base, and a substrate is placed thereon. Thereafter, the air pressure on the back surface side of the substrate is reduced lower than the air pressure on the front surface side to allow the adhesive sheet and the substrate to firmly adhere to each other. Then, the pressure difference is removed, and an elevating pin lifts the substrate from below the support base through a hole formed in each of the support base and the adhesive sheet to strip off the substrate from the adhesive sheet. Accordingly, the particles on the back surface of the substrate can be removed quickly, reliably and easily.

### BACKGROUND OF THE INVENTION

1. Field of the Invention

The present invention relates to an apparatus removing particles attached to a back surface of a substrate such as a semiconductor wafer, and a method thereof, and a technique of removing particles on a back surface of a substrate before exposure in a coating and development apparatus performing a resist liquid coating process and a development process after exposure.

2. Description of the Background Art

The manufacturing processes of semiconductor devices or LCD (liquid crystal display) substrates include a series of steps of forming a resist film on a substrate, exposing the resist film using a photomask and thereafter performing a development process to obtain a desired pattern. Such a process is generally performed using a system including a coating and development apparatus for coating of resist liquid and development and an exposure apparatus connected thereto.

Recently, device patterns are increasingly miniaturized and reduced in thickness, and accordingly the higher resolution of exposure is in increasing demand. Then, in order to achieve higher resolution of exposure, the exposure techniques have been developed using Extreme Ultra Violet Lithography (EUVL), Electron Projection Lithography (EPL), fluorinate dimmer (F2), or the like. On the other hand, in order to perform accurate exposure, the flatness of a substrate is required, and the exposure is influenced by particles attached to the back surface of the substrate and also by slight curvature of the substrate placed on an exposure stage affects the exposure.

Therefore, the back surface of a substrate is cleaned using a cleaning member such as a brush in a scrubber before the substrate is carried into a coating and development apparatus. However, the particles that are attached to the back surface of the substrate after the substrate is carried into the coating and development apparatus are brought into an exposure apparatus as they are. Then, at the exposure apparatus, as shown in FIG. 10A, for example, a number of needle-like protrusions 101 are provided at an exposure stage 100, so that particles 103 attached to the back surface of a substrate 102 intrude in between the protrusions and the back surface of substrate 102 is held by the protrusions. Therefore, local curvature of substrate 102 caused by particle 103 can be prevented, and as shown in FIG. 10B, the pattern is free from defects.

However, as shown in FIG. 11A, if the particle on the back surface of the substrate adheres at the position corresponding to the protrusion, that part is slightly raised and curved. Therefore, a focus position is shifted from the intended position, so that, for example, a defect of 2-3 mm in diameter occurs in a substrate after exposure, as shown in FIG. 11B.

Moreover, the scrubber is a large-scale apparatus in that it uses a cleaning liquid and moves a mechanism of reversing a substrate or a brush in a lateral direction relative to the substrate, and therefore it is not fit to be installed in a coating and development apparatus, in actuality.

Furthermore, in the field of semiconductor device manufacturing, if particles attach to the back surface of a substrate, those particles intrude into a process unit through a transfer arm for delivering a substrate or float through the gas to be transferred to the front surface of the substrate. Therefore, the back surface cleaning is important. For this purpose, a technique using an adhesive sheet is known as a simple particle removing device. For example, Japanese Patent Laying-Open No. 06-232108 (paragraphs 0013-0016, FIG. 1) discloses that a wafer edge is held by a jig, an adhesive sheet is brought into contact with the back surface of a wafer W, and the contact position is moved by rolling a roller.

However, this technique is far from realistic since a mechanism of extending the sheet at the upstream side and the downstream side of the roller is quite complicated, though not disclosed. In addition, the roller is not positioned in the vicinity of the peripheral portion of the wafer because of the presence of the jig, so that inconveniently, particles may be left over. Moreover, the delivery of substrates to/from the transfer arm is not considered, and the mechanism is less practicable.

### SUMMARY OF THE INVENTION

The present invention is made under the forgoing situations. An object of the present invention is to provide a method of removing particles on a substrate and an apparatus therefor, in which particles attached to the back surface of the substrate can be removed easily, reliably and quickly. Another object of the present invention is to provide a coating and development apparatus capable of removing particles attached to the back surface of a substrate easily, reliably and quickly before exposure to obtain a good resist pattern.

A method of removing a particle on a substrate in accordance with an aspect of the present invention includes the steps of: placing an adhesive sheet on a support base with an adhesive portion thereof facing up; placing a substrate on the adhesive sheet with a surface thereof facing up; reducing an air pressure on a back surface side lower than a front surface side of the substrate to allow a back surface of the substrate to firmly adhere to the adhesive portion of the adhesive sheet; removing a pressure difference between the front surface side and the back surface side of the substrate; and subsequently forcing the substrate up from below the support base by an elevating pin through a hole formed in each of the support base and the adhesive sheet to strip the substrate away from the adhesive sheet.

Preferably, the method further includes the step of pressing the adhesive sheet against the support base by an annular seal body surrounding the substrate to provide a hermetic partition between a region where the substrate is placed and a space below the support base.

Preferably, the substrate has a resist film formed thereon and is in a stage before exposure. A plurality of protrusions are formed on a surface of the support base corresponding to an arrangement pattern of protrusions formed on a surface of an exposure stage for use in exposure. The method further includes the step of performing registration before the substrate is placed on the support base such that a positional relation between an arrangement pattern of the protrusions of the support base and the substrate agrees with a positional relation between the arrangement pattern of the protrusions in the exposure stage and the substrate.

Preferably, the method further includes the step of displacing the adhesive sheet in a lateral direction in preparation for firm adhesion to a next substrate such that a contact part of the adhesive sheet with the protrusion of the support base is positioned not to be in contact with the protrusion, after the substrate is stripped away from the adhesive sheet.

Preferably, the method further includes the step of displacing the adhesive sheet in a lateral direction in preparation for firm adhesion to a next substrate, after the substrate is stripped away from the adhesive sheet.

A method of removing a particle on a substrate in accordance with another aspect of the present invention includes the steps of placing an adhesive sheet having a suction hole formed therein with an adhesive portion thereof facing up on a support base having a suction hole formed therein; placing a substrate with a surface thereof facing up on the adhesive sheet; sucking the substrate through the suction hole of the support base and the suction hole of the adhesive sheet to allow a back surface of the substrate to firmly adhere to the adhesive portion of the adhesive sheet; stopping suction of the substrate to remove a pressure difference between a front surface side and a back surface side of the substrate; subsequently stripping the substrate away from the adhesive sheet to allow a particle attached to the back surface of the substrate to be transferred to the adhesive portion of the adhesive sheet; and forcing the substrate up from below the support base by an elevating pin through a hole formed in each of the support base and the adhesive sheet to strip the substrate away from the adhesive sheet.

Preferably, the method further includes the step of pressing the adhesive sheet against the support base by an annular seal body surrounding the substrate to provide a hermetic partition between a region where the substrate is placed and a space below the support base.

Preferably, the substrate has a resist film formed thereon and is in a stage before exposure. A number of protrusions are formed on a surface of the support base corresponding to an arrangement pattern of protrusions formed on a surface of an exposure stage for use in exposure. The method further includes the step of performing registration before placing the substrate on the support base such that a positional relation between an arrangement pattern of protrusions of the support base and the substrate agrees with a positional relation between the arrangement pattern of protrusions in the exposure stage and the substrate.

Preferably, the method further includes the step of displacing the adhesive sheet in a lateral direction in preparation for firm adhesion to a next substrate such that a contact part of the adhesive sheet with the protrusion of the support base is positioned not to be in contact with the protrusion, after the substrate is stripped away from the adhesive sheet.

Preferably, the method further includes the step of displacing the adhesive sheet in a lateral direction in preparation for firm adhesion to a next substrate, after the substrate is stripped away from the adhesive sheet.

A substrate particle removing apparatus (A) in accordance with an aspect of the present invention includes: a support base for supporting a substrate; an adhesive sheet placed on the support base with an adhesive portion thereof facing up and having a substrate placed thereon with a surface thereof facing up; a part for reducing an air pressure on a back surface side lower than a front surface side of the substrate placed on the adhesive sheet to allow a back surface of the substrate to firmly adhere to the adhesive portion of the adhesive sheet; and an elevating pin provided to be insertable from below the support base to above the adhesive sheet through a hole formed in each of the support base and the adhesive sheet for delivering the substrate between the adhesive sheet and a substrate transfer part.

Preferably, the apparatus further includes an annular seal body pressing the adhesive sheet against the support base to provide a hermetic partition between a region where the substrate is placed and a space below the support base.

Preferably, the substrate has a resist film formed thereon and is in a stage before exposure. A number of protrusions are formed on a surface of the support base corresponding to an arrangement pattern of protrusions formed on a surface of an exposure stage for use in exposure. The apparatus further includes a registration part for performing registration before the substrate is placed on the support base such that a positional relation between an arrangement pattern of protrusions of the support base and the substrate agrees with a positional relation between the arrangement pattern of protrusions in the exposure stage and the substrate.

Preferably, the apparatus further includes an adhesive sheet transfer part for transferring the adhesive sheet in such a manner as to displace the adhesive sheet in a lateral direction such that a contact part of the adhesive sheet with the protrusion of the support base is positioned not to be in contact with the protrusion, after the substrate is stripped away from the adhesive sheet.

Preferably, the apparatus further includes an adhesive sheet transfer part for transferring the adhesive sheet in such a manner as to displace the adhesive sheet in a lateral direction in preparation for firm adhesion to a next substrate, after the substrate is stripped away from the adhesive sheet.

A substrate particle removing apparatus (B) in accordance with another aspect of the present invention includes: a support base having a suction hole formed therein for supporting a substrate; an adhesive sheet having a suction hole formed therein, placed on the support base with an adhesive portion thereof facing up, and having a substrate placed thereon; a suction part for sucking the substrate through each suction hole of the support base and the adhesive sheet to allow a back surface of the substrate to firmly adhere to the adhesive portion of the adhesive sheet; and an elevating pin provided to be insertable from below the support base to above the adhesive sheet through a hole formed in each of the support base and the adhesive sheet for delivering the substrate between the adhesive sheet and a substrate transfer part.

Preferably, the apparatus further includes an annular seal body pressing the adhesive sheet against the support base to provide a hermetic partition between a region where the substrate is placed and a space below the support base.

Preferably, the substrate has a resist film formed thereon and is in a stage before exposure. A number of protrusions are formed on a surface of the support base corresponding to an arrangement pattern of protrusions formed on a surface of an exposure stage for use in exposure. The apparatus further includes a registration part for performing registration before the substrate is placed on the support base such that a positional relation between an arrangement pattern of protrusions of the support base and the substrate agrees with a positional relation between the arrangement pattern of protrusions in the exposure stage and the substrate.

Preferably, the apparatus further includes an adhesive sheet transfer part for transferring the adhesive sheet in such a manner as to displace the adhesive sheet in a lateral direction in preparation for firm adhesion to a next substrate such that a contact part of the adhesive sheet with the protrusion of the support base is positioned not to be in contact with the protrusion, after the substrate is stripped away from the adhesive sheet.

Preferably, the apparatus further includes an adhesive sheet transfer part for transferring the adhesive sheet in such a manner as to displace the adhesive sheet in a lateral direction in preparation for firm adhesion to a next substrate, after the substrate is stripped away from the adhesive sheet.

A development apparatus in accordance with an aspect of the present invention is a coating and development apparatus coating a substrate with a resist liquid to form a resist film and performing a development process on the substrate after exposure. The apparatus includes: the substrate particle removing apparatus (A) for removing a particle on a back surface side of a substrate having a resist film formed on a front surface thereof before exposure is performed; and a substrate transfer part for delivering the substrate from/to the particle removing apparatus.

Preferably, the apparatus further includes: a process block coating a substrate with a resist liquid to form a resist film and performing a development process on a substrate after exposure; and an interface block for connecting the process block to an exposure apparatus. The substrate particle removing apparatus is provided in the interface block.

A development apparatus in accordance with another aspect of the present invention is a coating and development apparatus coating a substrate with a resist liquid to form a resist film and performing a development process on the substrate after exposure. The apparatus includes: the substrate particle removing apparatus (B) for removing a particle on a back surface side of a substrate having a resist film formed on a front surface thereof before exposure is performed; and a substrate transfer part for delivering the substrate from/to the particle removing apparatus.

Preferably, the apparatus further includes: a process block coating a substrate with a resist liquid to form a resist film and performing a development process on the substrate after exposure; and an interface block for connecting the process block to an exposure apparatus. The substrate particle removing apparatus is provided in the interface block.

In accordance with the present invention, an adhesive sheet is placed on a support base with an adhesive sheet portion thereof facing up, and a substrate is placed thereon. Thereafter, the air pressure on the back surface side of the substrate is reduced lower than the front surface side, for example, the substrate is sucked through a suction hole formed in the adhesive sheet, to allow the adhesive sheet and the substrate to firmly adhere to each other. Subsequently, the pressure difference is removed, and the substrate is lifted by an elevating pin form below the support base through a hole formed in each of the support base and the adhesive sheet and is then stripped away from the adhesive sheet. Therefore, the entire back surface (the part corresponding to each protrusion, if the support base has protrusions) of the substrate firmly adheres to the adhesive sheet under an uniform pressure. In addition, for example, a transfer arm holding the back surface of the substrate can be used to deliver the substrate. Moreover, the particles on the back surface of the substrate can be removed quickly, reliably and easily. Furthermore, a support base having protrusions corresponding to an exposure stage can be used to remove particles which adversely affect the exposure when the substrate is placed on the exposure stage, resulting in good patterns.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing an exemplary coating and development apparatus in accordance with the present invention.

FIG. 2 is an entire perspective view showing the coating and development apparatus.

FIG. 3 is a longitudinal cross sectional view showing an exemplary particle removing apparatus in accordance with the present invention.

FIG. 4 is a plan view of the particle removing apparatus.

FIGS. 5A, 5B are plan views showing an example of a support base and an adhesive tape in the particle removing apparatus.

FIG. 6 is a longitudinal cross sectional view showing an exemplary alignment mechanism for wafer registration.

FIG. 7 is a longitudinal cross sectional view showing an operation of the particle removing apparatus.

FIGS. 8A-8D are schematic diagrams showing a particle removing process in the particle removing apparatus.

FIG. 9 is a longitudinal cross sectional view showing an operation of the particle removing apparatus.

FIGS. 10A, 10B are schematic diagrams showing a positional relation between an exposure stage and a wafer in an exposure apparatus connected to the coating and development apparatus and a normal pattern on a wafer surface after exposure and development.

FIGS. 11A, 11B are schematic diagrams showing a positional relation between an exposure stage and a wafer in the event of abnormality in the exposure apparatus and a pattern of a surface of a wafer subjected to a subsequent development.

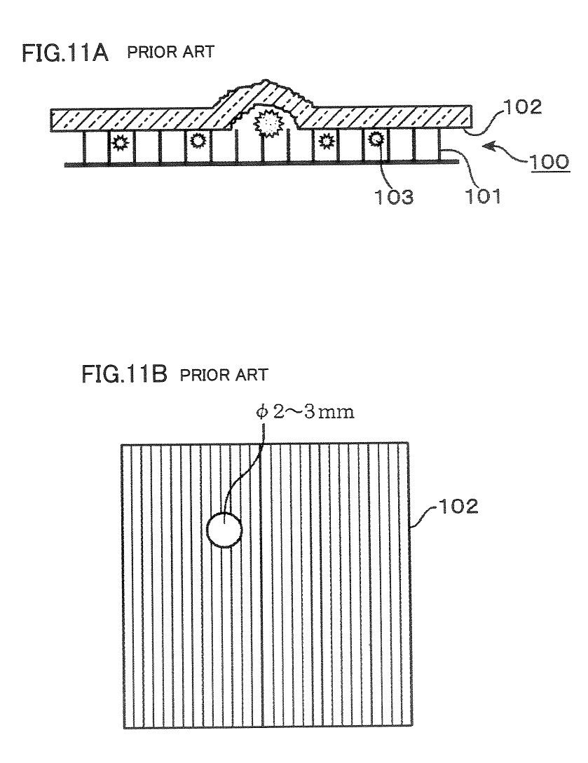

### DESCRIPTION OF THE PREFERRED EMBODIMENTS

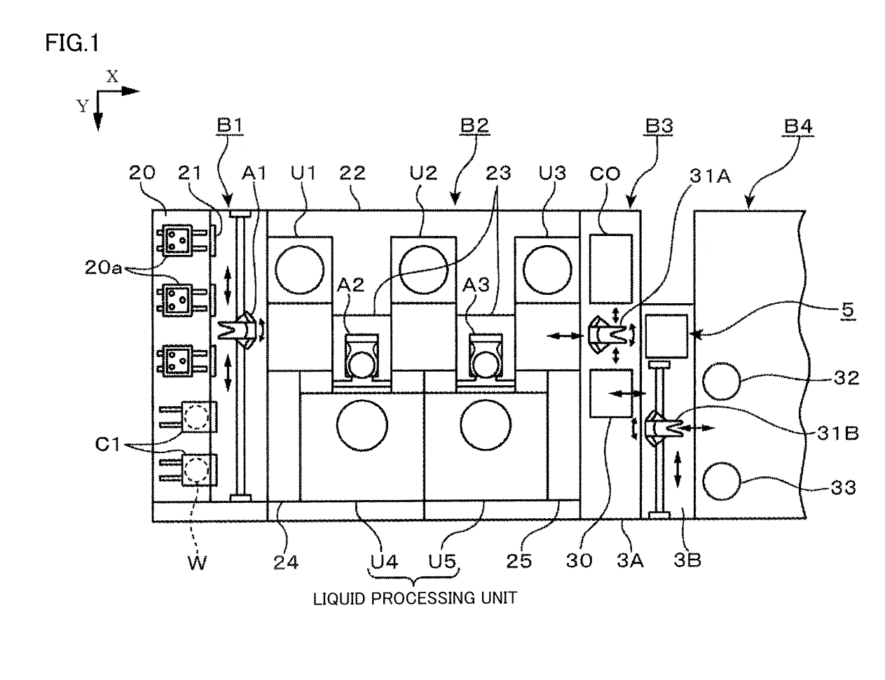

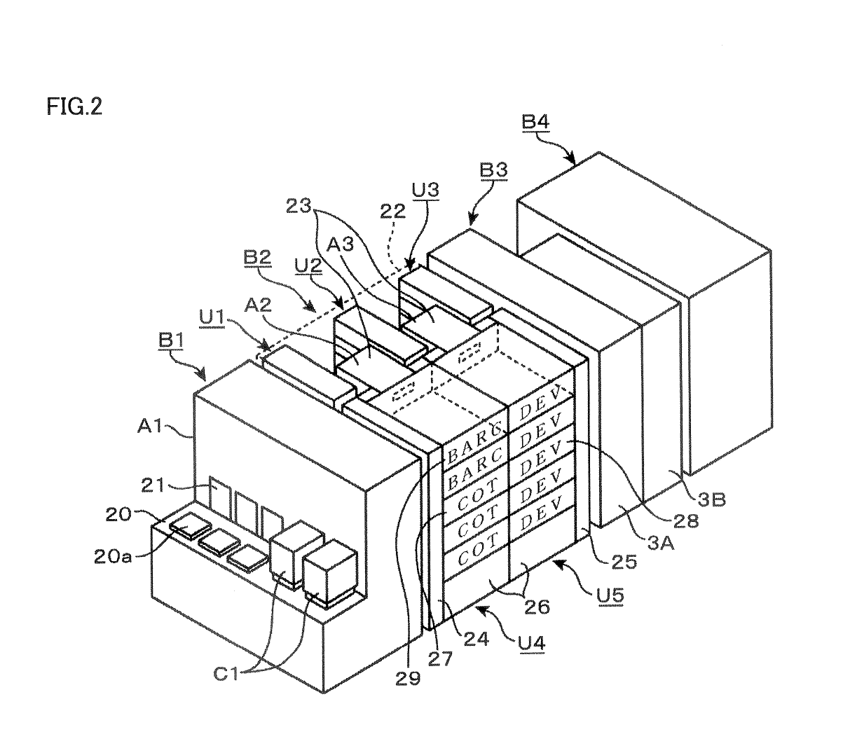

Referring to FIGS. 1 and 2, the configuration of the entire system including a coating and development apparatus will be described as a manner of carrying out a method of removing particles on a substrate in accordance with the present invention. This system includes a coating and development apparatus and an exposure apparatus connected thereto. In the figure, a carrier station B1 includes a carrier carry-in/out part 20 having a platform 20a for carrying in/out a carrier C1 hermetically accommodating substrates, for example, ten wafers W (referred to as wafer W hereinafter), an opening/closing part 21 provided on a wall surface of carrier carry-in/out part 20, and a transfer part A1 for delivering carrier C1 and wafer W through opening/closing part 21.

A process block B2 is provided inside a housing 22 provided at the back of carrier station B1. On the left side of process block B2, heating/cooling units U1, U2, U3 provided in multiple stages and transfer parts A2, A3 for wafer W installed inside a partition walls 23 are alternately provided in order from the front end. On the right side of process block B2, temperature/humidity adjustment units 24, 25 are installed on the front end and the back end, and liquid processing units U4, U5 provided in multiple stages are arranged inside thereof. Wafer W is delivered by transfer parts A2, A3 between liquid processing units U4, U5 and heating/cooling units U1, U2, U3. Temperature/humidity adjustment units 24, 25 each include a temperature adjuster or a duct for adjusting temperature and humidity to adjust the temperature of the process liquid used in each unit or the temperature and humidity of the air supplied to each unit.

Liquid processing units U4, U5 each include stacked multiple stages, for example, five stages of a coating unit (COT) 27, a development unit (DEV) 28, an antireflection coating formation unit (BARC) 29 and the like on a chemicals accommodation unit 26 for resist liquid, development liquid or the like. Furthermore, the aforementioned heating/cooling units U1, U2, U3 each include stacked multiple stages, for example, ten stages of a variety of units for performing pre-treatment and post-treatment of the process performed in liquid processing units U4, U5, including a heating unit for heating wafer W, a cooling unit for cooling wafer W, and the like.

At the back of process block B2, an exposure block B4 is connected with an interface block B3 interposed. Interface block B3 includes a first transfer room 3A and a second transfer room 3B provided from the process block B2 side. Provided inside first transfer room 3A are a buffer cassette CO, a wafer transfer part 31A, and a delivery unit 30 from the left side. It is noted that though not shown in the figure, a unit for exposing the periphery of wafer W is provided below buffer cassette CO.

A particle removing apparatus 5 and a wafer transfer part 31B are installed inside second transfer room 3B. A high-accuracy temperature-adjustment unit having a cooling plate and an alignment unit (neither shown) are additionally provided below particle removing apparatus 5. The transfer of wafer W between delivery unit 30, particle removing apparatus 5 and each unit is carried out by wafer transfer part 31B. A wafer carry-in stage 32 and a wafer carry-out stage 33 are provided in exposure block B4 so that wafer W is carried into/out of exposure block B4 through these stages 32, 33 by wafer transfer part 31B in second transfer room 3B.

Here, the entire process performed on wafer W in the system described above will be described briefly. First, carrier C1 hermetically accommodating wafer W is placed on platform 20a. Then, opening/closing part 21 and the cover of carrier C1 are opened so that wafer W is transferred to process block B2 from carrier C1 by transfer part A1. Thereafter, wafer W is transferred between heating/cooling units U1, U2 and antireflection coating formation unit (BARC) 29 by transfer part A2 so that an antireflection coating is formed or the temperature of wafer W is adjusted.

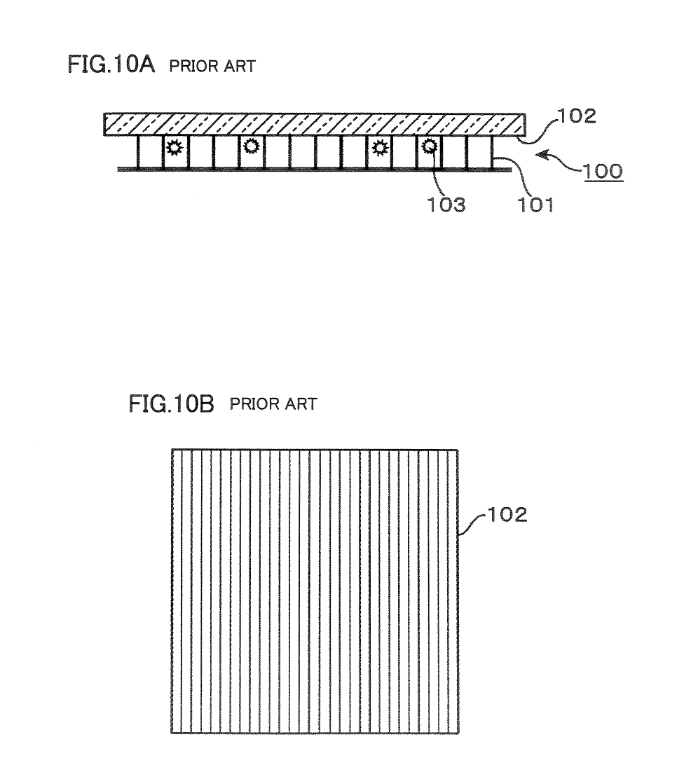

Then, wafer W is transferred into coating unit (COT) 27 by transfer part A2 so that a resist film is formed on the surface thereof. Wafer W having a resist film formed thereon is transferred to heating/cooling units U1-U3 by transfer parts A2, A3 so that a thermal process and cooling are carried out under a prescribed condition. Thereafter, wafer W is transferred to interface block B3 through the delivery unit in cooling unit U3. The wafer W carried into interface block B3 is subjected to edge exposure, is delivered from wafer transfer part 31A to wafer delivery part 31B through delivery unit 30, and is carried into particle removing apparatus 5 for a cleaning process (the particle removing process on the back surface of wafer W). Then, this wafer W is subjected to high-accuracy temperature adjustment by the temperature-adjustment unit and then transferred to exposure block B4 through carry-in stage 32 by wafer transfer part 31B. As shown in FIG. 10A, an exposure stage 100 provided with a number of needle-like protrusions 101 is installed in exposure block B4, and wafer W is exposed while being placed on these needle-like protrusions 101.

After completion of exposure, wafer W is carried out from exposure block B4 through carry-out stage 33 by wafer transfer part 31B and then transferred to heating unit (PEB) of heating/cooling unit U3 through delivery unit 30 for a heating process. As a result, acid is produced from the exposed portion to oxidize a resist component. For example, a positive resist becomes soluble to development liquid, and a negative resist becomes insoluble to development liquid.

Wafer W subjected to the heating process is transferred into development unit (DEV) 28 by wafer transfer part A3 so that a prescribed pattern is formed on the wafer W surface by development liquid. After a heating process and cooling is performed by heating/cooling units U2, U3, wafer W is returned into carrier C1 on platform 20a through the reverse path of carrying-in.

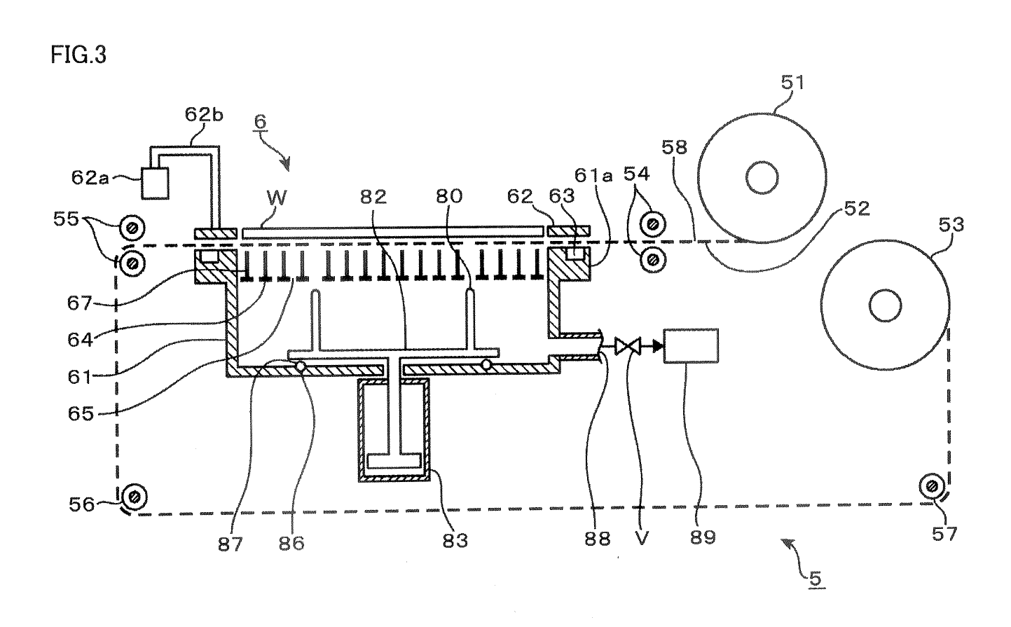

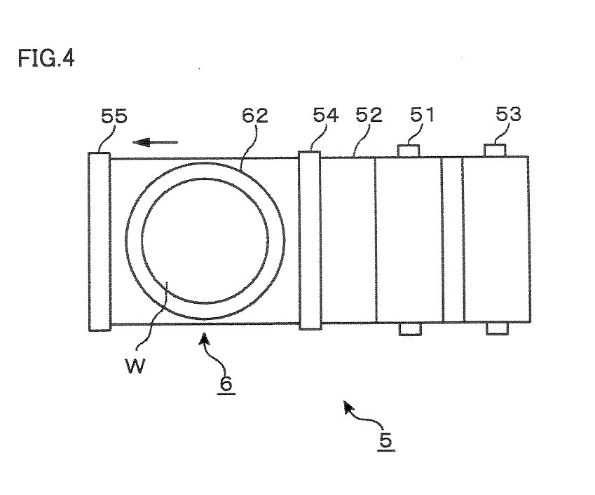

Referring now to FIGS. 3 and 4, a particle removing apparatus will be described as a manner of carrying out a method of removing particles on wafer W in accordance with the present invention. FIG. 3 is a longitudinal cross sectional view of particle removing apparatus 5 of the present invention. Particle removing apparatus 5 includes a particle removing portion 6 for removal of particles, a feed roll 51 of an adhesive sheet, an adhesive sheet 52 fed from feed roll 51, a take-up roll 53 of the adhesive sheet, onto which adhesive sheet 52 is wound, and adhesive sheet transfer rollers 54, 55, 56, 57 provided such that adhesive sheet 52 is transferred from feed roll 51 through the inside of particle removing portion 6 to be taken up by take-up roll 53. Feed roll 51 and take-up roll 53 may be installed anywhere as long as adhesive sheet 52 passes through the inside of particle removing portion 6. In this example, take-up roll 53 is installed on the same side as feed roll 51 with respect to particle removing portion 6. Feed roll 51, take-up roll 53 and transfer rollers 54-57 constitute an adhesive sheet transfer portion to transfer adhesive sheet 52.

Adhesive sheet 52 is transferred with its adhesive portion facing upward. Therefore, the upper transfer rollers of transfer rollers 54, 55 which are in contact with the adhesive portion are subjected to processing for preventing firm adhesion to adhesive sheet 52, for example, such as mirror-finishing, or a surface treatment, for example, such as fluorine resin coating.

Particle removing portion 6 includes a flat cylindrical housing 61 opened at the upper portion thereof and having an opening edge formed as a flange portion 61a, and an annular seal body 62 provided above flange portion 61a as opposed to flange portion 61a of housing 61 and having an inner diameter slightly, for example 1 mm, larger than the outer diameter of wafer W. Seal body 62 can be moved up and down by an elevator portion 62a through a support member 62b such that it can move up and down between the position where it is in intimate contact with flange portion 61a and the position where it is floated from flange 61a. Sealant 63 hermetically joins seal body 62 with flange 61b. Adhesive sheet 52 is transferred by the aforementioned adhesive sheet transfer portion between housing 61 and seal body 62 from the right to the left in FIG. 3. The lower surface of seal body 62 which is brought into contact with the adhesive portion of adhesive sheet 52 is subjected to the aforementioned processing or treatment similar to that of transfer rollers 54, 55 which are in contact with the adhesive portion of adhesive sheet 52.

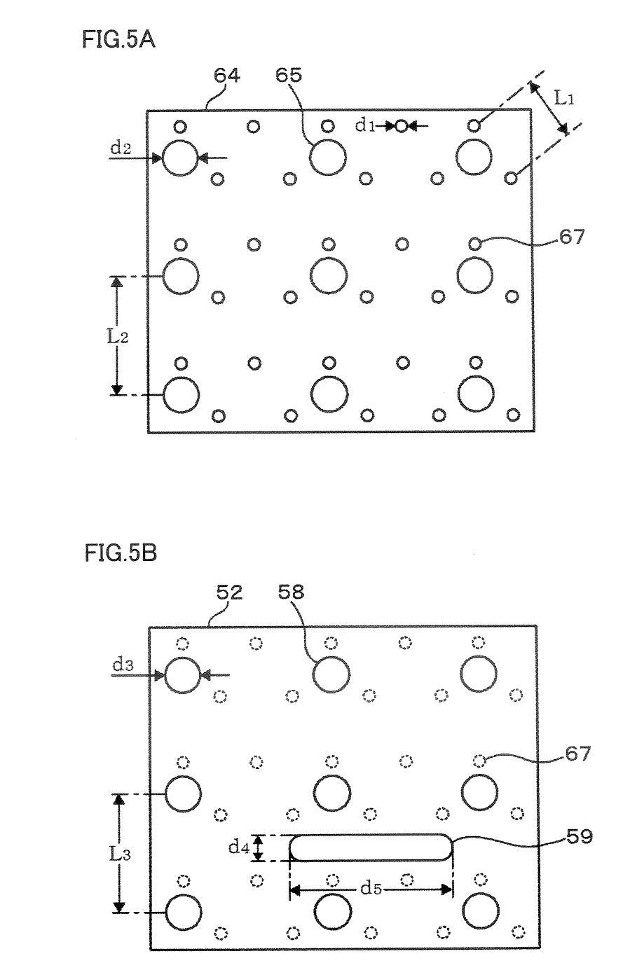

At the upper portion of housing 61, a support base 64 for a substrate is provided in such a manner as to block the opening portion of housing 61. Support base 61 is provided with a number of suction holes 65 and a number of wafer-holding protrusions 67 and fixed to housing 61 such that the upper surface of wafer-holding protrusion 67 attains a height in contact with the substrate side of adhesive sheet 52, that is, a height of the transfer surface. Then, as illustrated in the description of the background art with reference to FIG. 10A, exposure stage 100 in exposure block B4 is provided with protrusions 101. Wafer-holding protrusions 67 on support base 64 are set slightly longer (higher) than protrusions 101 provided on exposure stage 100 and arranged in a zigzag pattern corresponding to the arrangement pattern of protrusions 101. FIG. 5A shows an exemplary arrangement pattern of wafer-holding protrusions 67. In this example, wafer-holding protrusion 67 is made of a pin, for example, having a height of 0.1 mm and a diameter d1 of 0.5 mm and provided at a repetitive position of a vertex of a regular triangle having a side L1 of 3 mm. In addition, corresponding to the arrangement pattern of wafer-holding protrusions 67, suction hole 65 having a diameter d2 of 1.5 mm is provided at a repetitive position of a vertex of a square having a distance L2 of 6 mm.

The configuration of adhesive sheet 52 will be described with reference to FIG. 5B in relation with the arrangement of wafer-holding protrusions 67. A number of suction holes 58 are bored in adhesive sheet 52 in an arrangement pattern corresponding to the arrangement pattern of wafer-holding protrusions 67. In this example, suction hole 58 having a diameter d3 of 1.5 mm is provided, for example, at a repetitive position of a vertex of a square with a side having a length L3 of 6 mm. In addition, a long hole 59 with a shorter side d4 of 1.5 mm and a longer side d5 of 6 mm is provided at a part where a lift pin 80 passes through.

Here, long hole 59 is provided to allow lift pin 80 to pass through adhesive sheet 52 even after adhesive sheet 52 is slightly transferred such that the contact portion of adhesive sheet 52 with wafer-holding protrusion 67 of support base 64 is positioned not to be in contact with wafer-holding protrusion 67, as will be described later.

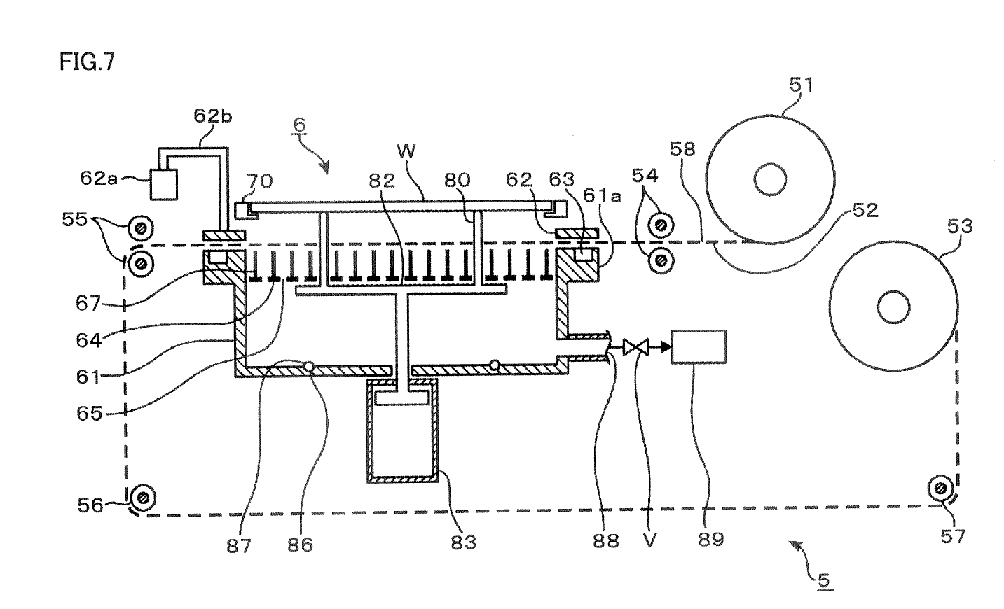

Lift pin 80 is installed under support base 64 to deliver wafer W between a substrate transfer portion 70 (see FIG. 7) provided above particle removing portion 6 and adhesive sheet 52 through suction hole 65 provided at support base 64 and long hole 59 provided in adhesive sheet 52.

A plurality of lift pins 80, for example, three, are prepared to move wafer W up and down in contact with wafer W and formed such that it moves up and down between a position below support base 64 and a position at which wafer W is forced upward for delivery from/to wafer transfer portion 70 using a driving portion 83, for example, an air cylinder with a base portion 82 interposed therebetween.

A ring-shaped groove 86 is provided at the lower part inside housing 61. An O-ring 87 which is a sealing material made of a resin (including rubber) is fitted into groove 86. Since O-ring 87 is provided on the inner circumferential side from the outer edge of base portion 82 of lift pin 80, it is brought into close contact with base portion 82 when lift pin 80 moves down to the lower part of housing 61.

A vacuum suction hole 88 is provided on a side surface of housing 61 and has its end connected to a vacuum pump 89 through a valve V so that housing 61 can be evacuated. When housing 61 is evacuated, adhesive sheet 52 is sucked to the support base 64 side, as will be described later, and wafer W is also sucked to the adhesive sheet 52 side, thereby allowing wafer W to firmly adhere to the adhesive portion of adhesive sheet 52.

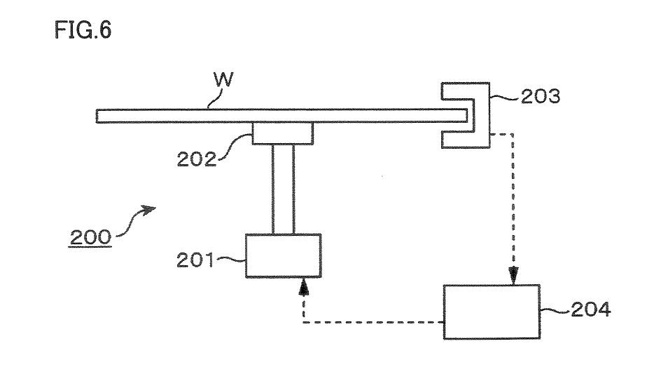

Here, a known alignment mechanism can be used as a registration unit for registering wafer W before being carried into particle removing apparatus 5. For example, as shown in FIG. 6, the mechanism is configured to include a vacuum chuck 202 rotated by a rotation mechanism 201, a light receiving/emitting portion 203 having an optical axis directed from the front surface to the back surface of the peripheral portion of wafer W placed on vacuum chuck 202, and a control portion 204. In this case, the peripheral position of wafer W is detected by light emitting/receiving portion 203 with wafer W rotated (360°), so that a reference portion such as orientation flat or notch formed in wafer W is detected by control portion 204 and rotation mechanism 201 is controlled such that the reference portion is set in a prescribed direction.

Accordingly, when wafer W is placed on support base 64 in particle removing apparatus 5, the positional relation between the arrangement pattern of wafer-holding protrusions 67 of support base 64 and wafer W is set in the intended direction, in other words, it becomes identical to their positional relation on exposure stage 100. It is noted that for the center registration of wafer W, the arm of wafer transfer portion 70 may provided with a guide member for holding wafer W with its center automatically registered by fitting the peripheral portion of wafer W in a horseshoe-shaped arm body. Vacuum chuck 202 may be configured to be movable in X, Y directions. The center of wafer W is detected based on periphery detection data of wafer W so that vacuum chuck 202 may be driven in X, Y directions such that the center is at a set position.

Now, the action of particle removing apparatus 5 in accordance with the embodiment of the present invention incorporated into the above-noted coating and development apparatus will be described.

First, as shown in FIG. 7, adhesive sheet 52 is stretched from feed roll 51 to take-up roll 53 through transfer roller 54, the inside of particle removing portion 6, and transfer rollers 55, 56, 57, and seal body 62 is moved down to be brought into close contact with adhesive sheet 52. Here, a part of each long hole 59 on adhesive sheet 52 at the downstream side in the transfer direction is set to be positioned corresponding to each lift pin 80. On the other hand, wafer W whose relative position with wafer-holding protrusion 67 of support base 64 is preliminarily adjusted by the registration unit shown in FIG. 6 is transferred to above particle removing portion 6 by wafer transfer portion 70. Lift pin 80 is moved upward through suction hole 65 of support base 64 and long hole 59 of adhesive tape 52 by driving portion 83 to force wafer W on wafer transfer portion 70 upward and receive wafer W. Thereafter, wafer transfer portion 70 is returned to a prescribed position. Then, lift pin 80 is moved downward by driving portion 83 to place wafer W onto adhesive tape 52, thereafter moves away from the back surface of wafer W, and moves down to the position where base portion 82 is brought into close contact with O-ring 82 provided at the lower part of housing 61.

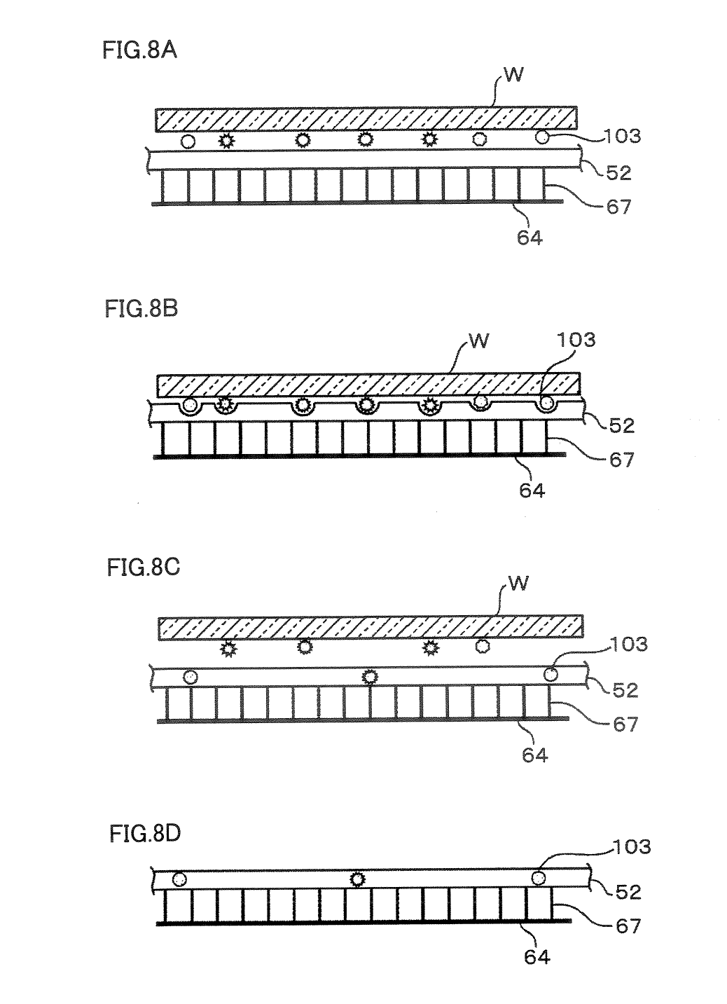

Thereafter, valve V is opened so that housing 61 is evacuated by vacuum pump 89. Wafer W firmly adheres to adhesive sheet 52, and particles attached to the back surface of wafer W are transferred to the adhesive portion of adhesive sheet 52. The state is shown in FIGS. 8A-8D. As shown in FIG. 8A, wafer W placed on adhesive sheet 52 does not evenly adhere to adhesive sheet 52 on the entire surface of wafer W as viewed microscopically. The part of mutual adhesion and the part having a minute gap are mixed, and wafer W adheres under a weak force corresponding to its own weight even at the part of mutual adhesion. Then, vacuum pump 89 is operated to evacuate housing 61, so that wafer W is sucked downward through suction hole 65 of support base 64 and suction hole 58 and long hole 59 of the adhesive sheet to firmly adhere to adhesive sheet 52, as shown in FIG. 8B. Here, adhesive sheet 52 is bent downward by the suction force at the part between wafer-holding protrusions 67 adjacent to each other and is supported at the part with wafer-holding protrusion 67. As a result, wafer W is strongly pressed against adhesive sheet 52 at this part, so that particle 103 attached to the back surface of wafer W at this part comes to adhere to adhesive sheet 52.

Thereafter, valve V is closed and a not-shown air supply path provided in a suction line connected to the suction hole is opened, so that the air pressure in housing 61 is returned to the air pressure at the upper surface of wafer W, that is, the air pressure equal to the atmospheric pressure. Then, as shown in FIG. 8C, when wafer W is stripped away from adhesive sheet 52 and is lifted by lift pin 80, of particles 103 attached to the back surface of wafer W, those particles 103 which are attached to the part corresponding to wafer-holding protrusions 67 of support base 64 are transferred to the adhesive portion of adhesive sheet 52.

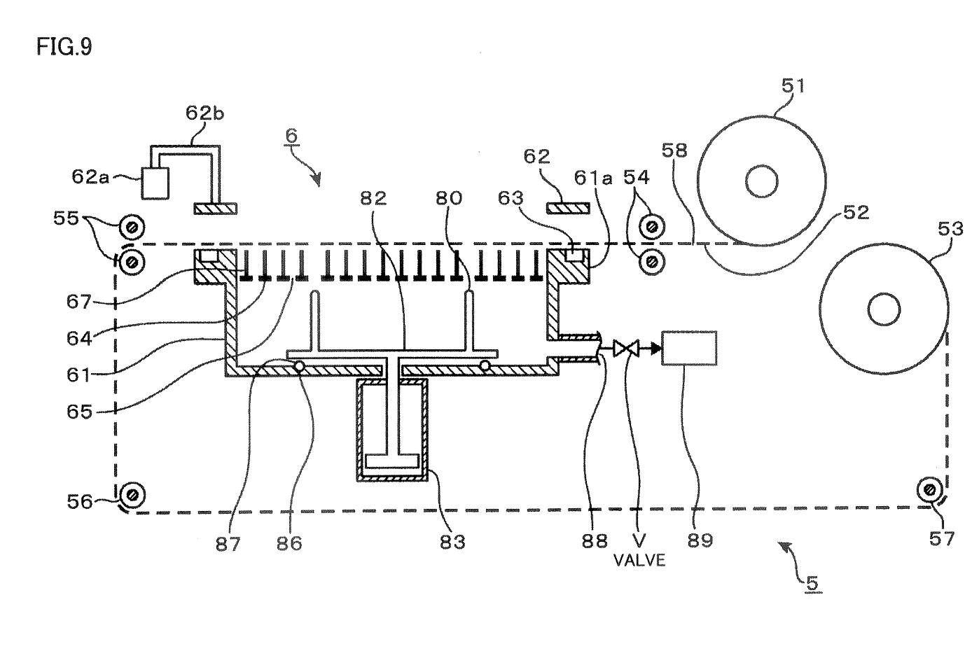

Thereafter, as shown in FIG. 9, seal body 62 is moved up so that the pressure on adhesive sheet 52 is removed. Adhesive sheet 52 is transferred from the right to the left (to the downstream side) in FIG. 9 in preparation for firm adhesion to the next wafer W. At that point, adhesive sheet 52 may be transferred for a distance corresponding to the diameter of wafer W. However, as described above, particle 103 is transferred to adhesive sheet 52 at the part corresponding to wafer-holding protrusion 67 of support base 64, and therefore, adhesive sheet 52 can be transferred such that the contact portion of adhesive sheet 52 with wafer-holding protrusion 67 of support base 64 is positioned not in contact with wafer-holding protrusion 67.

For example, the transfer amount of adhesive sheet 52 here may be set in relation with the distance between wafer-holding protrusions 67 adjacent to each other in the transfer direction, so that the entire surface region of adhesive sheet 52 on support base 64 can be used multiple times without being moved downstream as a whole. For example, as shown in FIG. 8D, adhesive sheet 52 may be used twice if moved by half the distance between wafer-holding protrusions 67 as shown in FIG. 8D or may be used three times if moved by 2 mm each time in the forgoing dimensional example. In this way, the amount of use of adhesive sheet 52 can be reduced without adversely affecting the effect of removing particles attached to wafer W, thereby reducing the costs. It is noted that particles 103 once transferred to adhesive sheet 52 strongly and firmly adhere to adhesive sheet 52, so that they are taken up by take-up roll 53 together with adhesive sheet 52 without being retransferred to wafer W or dropped off later.

In the present invention, adhesive sheet 52 is placed on support base 64 having protrusion portions 67 arranged corresponding to the exposure stage and the registered wafer W is placed thereon. Thereafter, wafer W is sucked through adhesive sheet 52 and suction hole 65 formed in support base 64 so that adhesive sheet 52 and wafer W firmly adhere to each other. Therefore, it is possible to remove particles on the back surface side of wafer W, that is, particles attached to the part corresponding to protrusion portion 67 which adversely affect exposure when wafer W is placed on the exposure stage. Thus, exposure can be performed well, and development defects can be reduced, thereby preventing reduced yields.

Then, the suction is released, and wafer W is lifted by lift pin 80 from below support base 64 through the holes each formed in support base 64 and adhesive sheet 52 and is then stripped away from adhesive sheet 52. Therefore, wafer W can be delivered from/to transfer arm 70 holding the back surface of wafer W. In addition, adhesive sheet 52 is stretched between feed roller 51 and take-up roller 53 and is pressed by seal body 62 around the wafer W placement region. After removing the pressing, adhesive sheet 52 is transferred. Accordingly, the particles on the back surface of wafer W can be removed quickly, reliably and easily. The present invention is thus suitably provided in the system for resist patterns requiring high throughput, resulting in good patterns.

Here, the hole of adhesive sheet 52 through which lift pin 80 passes may also serve as suction hole 58 instead of serving as a dedicated hole for lift pin 80. In this case, if suction hole 58 and lift pin 80 are misaligned in a planar direction when adhesive sheet 52 is slightly displaced after completion of removal of particles on wafer W, for example, a movement mechanism which is movable in the transfer direction of adhesive sheet 52 may be provided at lift pin 80 so that their positions correspond to each other.

In the foregoing example, wafer W is pressed against support base 64 with adhesive sheet 52 interposed therebetween by setting the air pressure on the back surface side lower than the air pressure on the front surface side of wafer W. However, for example, wafer W may be pressed against support base 64 by sealing the region on which wafer W is placed and pressurizing this sealed space so that the air pressure on the front surface side of wafer W is higher than the air pressure on the back surface side.

Furthermore, in the foregoing example, protrusion portions 67 are provided on support base 64. However, in particle removing apparatus 5 of the present invention, adhesive sheet 52 may be arranged on support base 64 including a flat support surface without protrusion portion 67 and the entire back surface of wafer W may be pressed against adhesive sheet 52. Moreover, particle removing apparatus 5 of the present invention may not necessarily be provided in interface block B3 but may be provided, for example, between process block B2 and interface block B3 or may not necessarily be provided in the coating and development apparatus but may be provided in exposure apparatus B4. In addition, particle removing apparatus 5 of the present invention may not necessarily be provided in the system for forming a resist pattern but may be provided in combination with other semiconductor manufacturing apparatuses or may be configured as a signal apparatus.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A method of removing a particle on a substrate comprising the steps of:
placing an adhesive sheet on a support base with an adhesive portion thereof facing up;
placing a substrate on said adhesive sheet with a surface thereof facing up;
reducing an air pressure on a back surface side lower than a front surface side of said substrate to allow a back surface of said substrate to firmly adhere to the adhesive portion of said adhesive sheet;
removing a pressure difference between the front surface side and the back surface side of said substrate; and
subsequently forcing said substrate up from below said support base by an elevating pin through a hole formed in each of said support base and said adhesive sheet to strip said substrate away from said adhesive sheet.

2. The method of removing a particle on a substrate according to claim 1, further comprising the step of pressing said adhesive sheet against said support base by an annular seal body surrounding said substrate to provide a hermetic partition between a region where said substrate is placed and a space below said support base.

3. The method of removing a particle on a substrate according to claim 1, wherein
said substrate has a resist film formed thereon and is in a stage before exposure, and
a plurality of protrusions are formed on a surface of said support base corresponding to an arrangement pattern of protrusions formed on a surface of an exposure stage for use in exposure,
said method further comprising the step of performing registration before said substrate is placed on said support base such that a positional relation between an arrangement pattern of said protrusions of said support base and said substrate agrees with a positional relation between the arrangement pattern of the protrusions in said exposure stage and said substrate.

4. The method of removing a particle on a substrate according to claim 3, further comprising the step of displacing said adhesive sheet in a lateral direction in preparation for firm adhesion to a next substrate such that a contact part of said adhesive sheet with the protrusion of said support base is positioned not to be in contact with the protrusion, after said substrate is stripped away from said adhesive sheet.

5. The method of removing a particle on a substrate according to claim 1, further comprising the step of displacing said adhesive sheet in a lateral direction in preparation for firm adhesion to a next substrate, after said substrate is stripped away from said adhesive sheet.

6. A method of removing a particle on a substrate comprising the steps of:
placing an adhesive sheet having a suction hole formed therein with an adhesive portion thereof facing up on a support base having a suction hole formed therein;
placing a substrate with a surface thereof facing up on said adhesive sheet;
sucking said substrate through the suction hole of said support base and the suction hole of said adhesive sheet to allow a back surface of said substrate to firmly adhere to the adhesive portion of said adhesive sheet;
stopping suction of said substrate to remove a pressure difference between a front surface side and a back surface side of said substrate;
subsequently stripping said substrate away from said adhesive sheet to allow a particle attached to the back surface of said substrate to be transferred to the adhesive portion of said adhesive sheet; and
forcing said substrate up from below said support base by an elevating pin through a hole formed in each of said support base and said adhesive sheet to strip said substrate away from said adhesive sheet.

7. The method of removing a particle on a substrate according to claim 6, further comprising the step of pressing said adhesive sheet against said support base by an annular seal body surrounding said substrate to provide a hermetic partition between a region where said substrate is placed and a space below said support base.

8. The method of removing a particle on a substrate according to claim 7, wherein
said substrate has a resist film formed thereon and is in a stage before exposure, and
a number of protrusions are formed on a surface of said support base corresponding to an arrangement pattern of protrusions formed on a surface of an exposure stage for use in exposure,
said method further comprising the step of performing registration before placing said substrate on said support base such that a positional relation between an arrangement pattern of protrusions of said support base and said substrate agrees with a positional relation between the arrangement pattern of protrusions in said exposure stage and said substrate.

9. The method of removing a particle on a substrate according to claim 8, further comprising the step of displacing said adhesive sheet in a lateral direction in preparation for firm adhesion to a next substrate such that a contact part of the adhesive sheet with the protrusion of said support base is positioned not to be in contact with the protrusion, after said substrate is stripped away from said adhesive sheet.

10. The method of removing a particle on a substrate according to claim 6, further comprising the step of displacing said adhesive sheet in a lateral direction in preparation for firm adhesion to a next substrate, after said substrate is stripped away from said adhesive sheet.

11. A substrate particle removing apparatus comprising:
a support base for supporting a substrate;
an adhesive sheet placed on said support base with an adhesive portion thereof facing up and having a substrate placed thereon with a surface thereof facing up;
means for reducing an air pressure on a back surface side lower than a front surface side of the substrate placed on the adhesive sheet to allow a back surface of the substrate to firmly adhere to the adhesive portion of said adhesive sheet; and
an elevating pin provided to be insertable from below said support base to above said adhesive sheet through a hole formed in each of said support base and said adhesive sheet for delivering the substrate between said adhesive sheet and substrate transfer means.

12. The substrate particle removing apparatus according to claim 11, further comprising an annular seal body pressing said adhesive sheet against said support base to provide a hermetic partition between a region where said substrate is placed and a space below said support base.

13. The substrate particle removing apparatus according to claim 11, wherein
said substrate has a resist film formed thereon and is in a stage before exposure, and
a number of protrusions are formed on a surface of said support base corresponding to an arrangement pattern of protrusions formed on a surface of an exposure stage for use in exposure,
the apparatus further comprising registration means for performing registration before said substrate is placed on said support base such that a positional relation between an arrangement pattern of protrusions of said support base and said substrate agrees with a positional relation between the arrangement pattern of protrusions in the exposure stage and said substrate.

14. The substrate particle removing apparatus according to claim 13, further comprising adhesive sheet transfer means for transferring the adhesive sheet in such a manner as to displace the adhesive sheet in a lateral direction such that a contact part of the adhesive sheet with the protrusion of the support base is positioned not to be in contact with the protrusion, after said substrate is stripped away from said adhesive sheet.

15. The substrate particle removing apparatus according to claim 11, further comprising adhesive sheet transfer means for transferring the adhesive sheet in such a manner as to displace the adhesive sheet in a lateral direction in preparation for firm adhesion to a next substrate, after said substrate is stripped away from said adhesive sheet.

16. A substrate particle removing apparatus comprising:
a support base having a suction hole formed therein for supporting a substrate;
an adhesive sheet having a suction hole formed therein, placed on said support base with an adhesive portion thereof facing up, and having a substrate placed thereon;
suction means for sucking the substrate through each suction hole of said support base and said adhesive sheet to allow a back surface of said substrate to firmly adhere to the adhesive portion of said adhesive sheet; and
an elevating pin provided to be insertable from below said support base to above said adhesive sheet through a hole formed in each of said support base and said adhesive sheet for delivering the substrate between said adhesive sheet and substrate transfer means.

17. The substrate particle removing apparatus according to claim 16, further comprising an annular seal body pressing said adhesive sheet against said support base to provide a hermetic partition between a region where said substrate is placed and a space below said support base.

18. The substrate particle removing apparatus according to claim 16, wherein
said substrate has a resist film formed thereon and is in a stage before exposure, and
a number of protrusions are formed on a surface of said support base corresponding to an arrangement pattern of protrusions formed on a surface of an exposure stage for use in exposure,
the apparatus further comprising registration means for performing registration before said substrate is placed on said support base such that a positional relation between an arrangement pattern of protrusions of said support base and said substrate agrees with a positional relation between the arrangement pattern of protrusions in the exposure stage and said substrate.

19. The substrate particle removing apparatus according to claim 18, further comprising adhesive sheet transfer means for transferring the adhesive sheet in such a manner as to displace the adhesive sheet in a lateral direction in preparation for firm adhesion to a next substrate such that a contact part of the adhesive sheet with the protrusion of the support base is positioned not to be in contact with the protrusion, after said substrate is stripped away from said adhesive sheet.

20. The substrate particle removing apparatus according to claim 16, further comprising adhesive sheet transfer means for transferring the adhesive sheet in such a manner as to displace the adhesive sheet in a lateral direction in preparation for firm adhesion to a next substrate, after said substrate is stripped away from said adhesive sheet.

21. A coating and development apparatus coating a substrate with a resist liquid to form a resist film and performing a development process on the substrate after exposure, comprising:
the substrate particle removing apparatus according to claim 11 for removing a particle on a back surface side of a substrate having a resist film formed on a front surface thereof before exposure is performed; and
substrate transfer means for delivering the substrate from/to said particle removing apparatus.

22. The coating and development apparatus according to claim 21, further comprising: a process block coating a substrate with a resist liquid to form a resist film and performing a development process on a substrate after exposure; and an interface block for connecting said process block to an exposure apparatus, wherein said substrate particle removing apparatus is provided in said interface block.

23. A coating and development apparatus coating a substrate with a resist liquid to form a resist film and performing a development process on the substrate after exposure, comprising:
the substrate particle removing apparatus according to claim 16 for removing a particle on a back surface side of a substrate having a resist film formed on a front surface thereof before exposure is performed; and
substrate transfer means for delivering the substrate from/to said particle removing apparatus.

24. The coating and development apparatus according to claim 23, further comprising: a process block coating a substrate with a resist liquid to form a resist film and performing a development process on the substrate after exposure; and an interface block for connecting said process block to an exposure apparatus, wherein said substrate particle removing apparatus is provided in said interface block.
